(19) United States
(12) Patent Application Publication
(10) Pub. No.: US 2013/0222603 A1
(43) Pub. Date: Aug. 29, 2013

(54) IMAGING SYSTEMS FOR INFRARED AND VISIBLE IMAGING

(71) Applicant: Aptina Imaging Corporation, (US)

(72) Inventors: Gennadiy Agranov, San Jose, CA (US); Dongqing Cao, San Jose, CA (US); Richard Holscher, Boise, ID (US)

(73) Assignee: Aptina Imaging Corporation, George Town (KY)

(21) Appl. No.: 13/777,776

(22) Filed: Feb. 26, 2013

Related U.S. Application Data
(60) Provisional application No. 61/604,451, filed on Feb. 28, 2012.

(51) Int. Cl. H04N 5/33

(52) U.S. Cl. CPC H04N 5/33
USPC 348/164

(57) ABSTRACT

An imaging device capable of simultaneously capturing visible and infrared images may be provided with an array of photosensitive elements, an array of filter elements arranged over the array of photosensitive elements, and a dual bandpass filter arranged over the array of filter elements. The dual bandpass filter may have a first passband in the visible spectral range and a second passband in the infrared spectral range. The array of filter elements may include color filter elements and infrared filter elements. During color image capturing operations, each color pixel receives visible and near infrared light through the dual bandpass filter and an associated color filter element. The infrared portion of the pixel signal from the color pixels may be removed using signals from the near infrared pixels. During infrared image capturing operations, each near infrared pixel receives infrared light through the dual bandpass filter and an associated infrared filter element.

This application claims the benefit of provisional patent application No. 61/604,451, filed Feb. 28, 2012, which is hereby incorporated by reference herein in its entirety.

### BACKGROUND

This relates generally to imaging devices, and more particularly, to imaging devices with both visible and infrared imaging capabilities.

Modern electronic devices such a cellular telephones, cameras, and computers often use digital image sensors. Imagers (i.e., image sensors) may be formed from a two-dimensional array of image sensing pixels. Each pixel may include a photosensor such as a photodiode that receives incident photons (light) and converts the photons into electrical signals. Image sensors are sometimes designed to provide images to electronic devices using a Joint Photographic Experts Group (JPEG) format or any other suitable image format.

Imaging devices may be configured to capture images in both the infrared spectral range as well as the visible spectral range. Infrared imaging can be used for a number of different applications such as three-dimensional (3D) imaging, automatic focusing, and other applications. In conventional image sensors, however, it can be difficult to separate signals corresponding to infrared light from signals corresponding to visible light. If care is not taken, infrared light received by color pixels in the image sensor can degrade the quality of images captured in the visible spectrum.

An infrared cut-off filter is sometimes placed in front of the image sensor to prevent infrared light from striking the image sensor. In order to capture images in the infrared spectral range, a separate imaging sensor is used for infrared imaging. However, the use of two separate imaging sensors is costly and can add undesirable bulk to an electronic device.

It would therefore be desirable to be able to provide improved imaging devices for capturing images in both the infrared and the visible spectral ranges.

### BRIEF DESCRIPTION OF THE DRAWINGS

FIG. 1 is a diagram of an illustrative electronic device having a camera module in accordance with an embodiment of the present invention.

FIG. 2 is a graph showing the spectral response of a dual bandpass filter that may be used in a camera module of the type shown in FIG. 1 in accordance with an embodiment of the present invention.

FIG. 3 is a top view of a pixel array that includes both color pixels and near infrared pixels in accordance with an embodiment of the present invention.

FIG. 4 is a graph showing the quantum efficiency of an illustrative green pixel that may be used in an image sensor of the type shown in FIG. 1 in accordance with an embodiment of the present invention.

FIG. 5 is a graph showing the quantum efficiency of an illustrative red pixel that may be used in an image sensor of the type shown in FIG. 1 in accordance with an embodiment of the present invention.

FIG. 6 is a graph showing the quantum efficiency of an illustrative blue pixel that may be used in an image sensor of the type shown in FIG. 1 in accordance with an embodiment of the present invention.

FIG. 7 is a graph showing the quantum efficiency of an illustrative near infrared pixel in accordance with an embodiment of the present invention.

FIG. 8 is a cross-sectional side view of a portion of an illustrative image sensor of the type shown in FIG. 1 in accordance with an embodiment of the present invention.

FIG. 9 is a flow chart of illustrative steps involved in simultaneously capturing images in the visible spectral range and the infrared spectral range using an electronic device of the type shown in FIG. 1 in accordance with an embodiment of the present invention.

FIG. 10 is a block diagram of an imager employing the embodiments of FIGS. 1-9 in accordance with an embodiment of the present invention.

### DETAILED DESCRIPTION

Electronic devices such as digital cameras, computers, cellular telephones, and other electronic devices include image sensors that gather incoming image light to capture an image. The image sensors may include arrays of imaging pixels. The pixels in the image sensors may include photosensitive elements such as photodiodes that convert the incoming image light into image signals. Image sensors may have any number of pixels (e.g., hundreds or thousands or more). A typical image sensor may, for example, have hundreds of thousands or millions of pixels (e.g., megapixels). Image sensors may include control circuitry such as circuitry for operating the imaging pixels and readout circuitry for reading out image signals corresponding to the electric charge generated by the photosensitive elements.

Imagers may be provided with color filter arrays. A color filter array may include an array of red color filter elements, green color filter elements, blue color filter elements, and infrared filter elements formed over an array of photosensors. Each filter in the color filter array may be optimized to pass one or more wavelength bands of the electromagnetic spectrum. For example, red color filters may be optimized to pass a wavelength band corresponding to red light, blue color filters may be optimized to pass a wavelength band corresponding to blue light, green color filters may be optimized to pass a wavelength band corresponding to green light, and infrared filters may be optimized to pass a wavelength band corresponding to infrared light. Various interpolation and signal processing schemes may be used to construct a full-color image using the image data which is gathered from an imager having a color filter array.

The red, green, and blue color filters may be configured to pass both visible and infrared light, whereas the infrared filters may be configured to block visible light while passing infrared light. A dual bandpass filter may be arranged over the image sensor. The dual bandpass filter may have a main passband in the visible spectral range and a narrow passband in the infrared spectral range.

With this type of configuration, the image sensor may be configured to simultaneously capture images in the visible spectral range and the infrared spectral range. For example, the imaging device may include an emitter that illuminates a scene with infrared light having a wavelength that falls within the narrow passband of the dual bandpass filter. Each near infrared pixel in the image sensor (i.e., each pixel over which an infrared filter is formed) may receive reflected infrared light from the scene through the dual bandpass filter and an associated infrared filter. Each color pixel in the image sensor (i.e., each pixel over which a color filter is formed) may receive visible light and reflected infrared light from the scene through the dual bandpass filter and an associated color filter. For capturing images in the infrared spectral range, pixel signals from the near infrared pixels may be used to form infrared images. Because the color pixels are also configured to receive infrared light, the color pixels may, if desired, be used to assist in capturing images in the infrared spectral range. For capturing images in the visible spectral range, signals from the near infrared pixels can be used to improve the quality of the color images. For example, the infrared portion of a color pixel signal can be removed based on signals from the near infrared pixels.

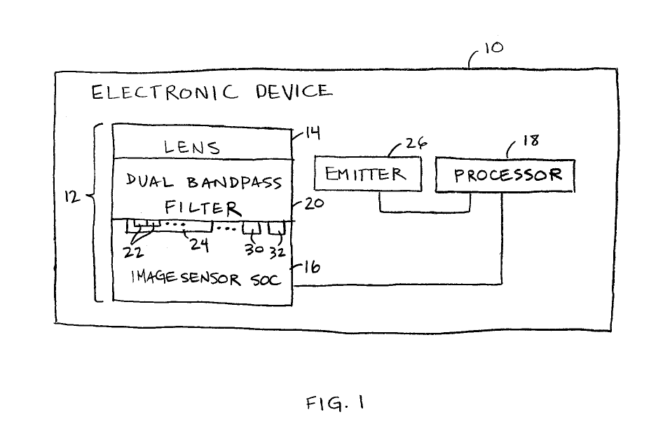

FIG. 1 is a diagram of an illustrative electronic device that uses an image sensor to capture images. Electronic device 10 of FIG. 1 may be a portable electronic device such as a camera, a cellular telephone, a video camera, or other imaging device that captures digital image data. Camera module 12 may be used to convert incoming light into digital image data. Camera module 12 may include one or more lenses 14 and one or more corresponding image sensors 16. Image sensor 16 may be an image sensor system-on-chip (SOC) having additional processing and control circuitry such as analog control circuitry and digital control circuitry on a common image sensor integrated circuit die with an image pixel array.

During image capture operations, light from a scene may be focused onto an image pixel array (e.g., array 24 of image pixels 22) by lens 14. Image sensor 16 provides corresponding digital image data to analog circuitry 30. Analog circuitry 30 may provide processed image data to digital circuitry 32 for further processing. Circuitry 30 and/or 32 may also be used in controlling the operation of image sensor 16. Image sensor 16 may, for example, be a backside illumination image sensor. If desired, camera module 12 may be provided with an array of lenses 14 and an array of corresponding image sensors 16.

Device 10 may include additional control circuitry such as storage and processing circuitry 18. Circuitry 18 may include one or more integrated circuits (e.g., image processing circuits, microprocessors, storage devices such as random-access memory and non-volatile memory, etc.) and may be implemented using components that are separate from camera module 12 and/or that form part of camera module 12 (e.g., circuits that form part of an integrated circuit that includes image sensors 16 or an integrated circuit within module 12 that is associated with image sensors 16). Image data that has been captured by camera module 12 may be further processed and/or stored using processing circuitry 18. Processed image data may, if desired, be provided to external equipment (e.g., a computer or other device) using wired and/or wireless communications paths coupled to processing circuitry 18. Processing circuitry 18 may be used in controlling the operation of image sensors 16.

Image sensors 16 may include one or more arrays 24 of image pixels 22. Image pixels 22 may be formed in a semiconductor substrate using complementary metal-oxide-semiconductor (CMOS) technology or charge-coupled device (CCD) technology or any other suitable photosensitive devices.

A filter such as dual bandpass filter 20 may be interposed between lens 14 and image sensor 16. Filter 20 may, for example, be a bandpass coating filter that includes multiple layers of coating on a glass substrate. Using a process of constructive and destructive interference, filter 20 may be configured to pass a first band of wavelengths corresponding to visible light and a second narrow band of wavelengths corresponding to near infrared light.

Filter 20 may allow image sensor 16 to simultaneously capture images in the visible spectral range and in the infrared spectral range. For example, device 10 may include an emitter such as infrared emitter 26. Infrared emitter 26 may be an infrared laser that is used to illuminate a scene with near infrared light. The light generated by emitter 26 may be structured light having a wavelength that falls within the second narrow passband of filter 20. During infrared imaging operations, infrared light that is reflected from a scene towards image sensor 16 will pass through filter 20 and will be detected by pixels 22 in pixel array 24.

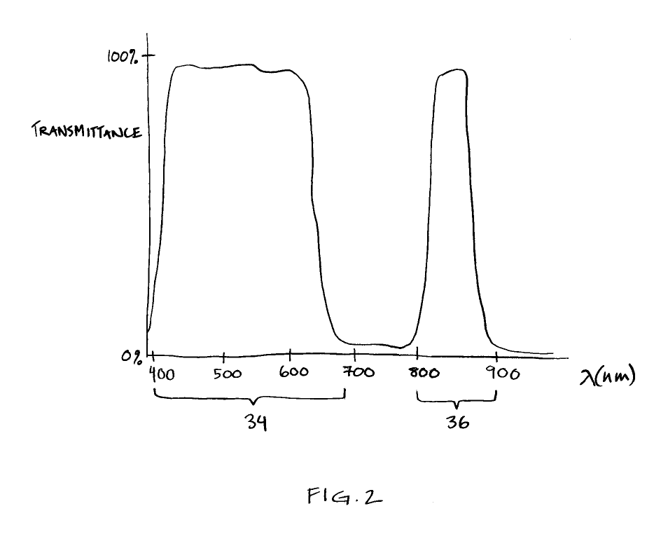

A graph showing the spectral response of dual bandpass filter 20 is shown in FIG. 2. As shown in FIG. 2, dual bandpass filter 20 may have a first passband such as passband 34 in the visible spectral range and a second narrow passband such as passband 36 in the infrared spectral range. First passband 34 may correspond to wavelengths ranging from about 390 to about 650 nanometers, whereas second passband 36 may correspond to wavelengths ranging from about 830 to about 870 nanometers, about 830 to about 930 nanometers, or may correspond to other suitable ranges of wavelengths in the infrared spectral range.

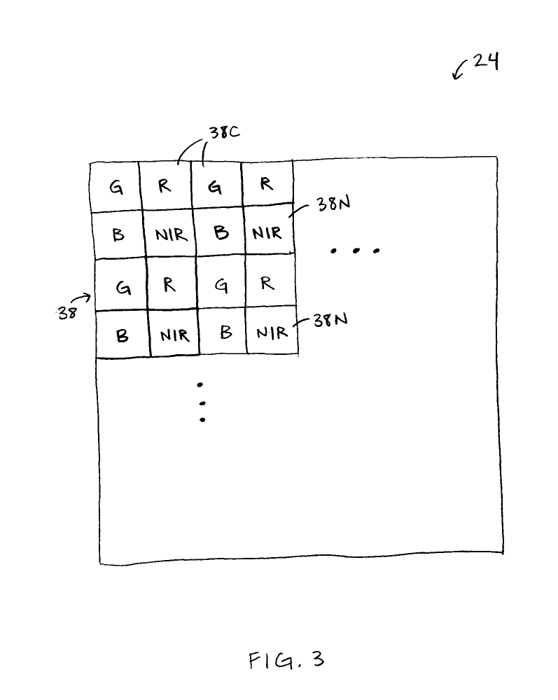

An array of color filters and infrared filters may be formed over photosensitive elements of pixel array 24 to allow for simultaneous visible and infrared imaging. FIG. 3 is a top view of an illustrative pixel array that includes an array of filter elements such as color filter array 38. Color filter array 38 may include color filters such as color filters 38C and infrared filters such as infrared filters 38N. Each filter may be formed over an associated photosensor. Pixels that include color filters 38C are sometimes referred to herein as “color pixels.” Pixels that include infrared filters 38N are sometimes referred to as “near infrared pixels” or “infrared pixels.”

Each filter in the color filter array may be optimized to pass one or more wavelength bands of the electromagnetic spectrum. For example, red color filters may be optimized to pass a wavelength band corresponding to red light, blue color filters may be optimized to pass a wavelength band corresponding to blue light, green color filters may be 2 0 optimized to pass a wavelength band corresponding to green light, and infrared filters may be optimized to pass a wavelength band corresponding to infrared light.

Color pixels and infrared pixels may be arranged in any suitable fashion. In the example of FIG. 3, color filter array 38 is formed in a “quasi-Bayer” pattern. With this type of arrangement, array 38 is composed of 2×2 blocks of filter elements in which each block includes a green color filter element, a red color filter element, a blue color filter element, and a near infrared filter element in the place where a green color filter element would be located in a typical Bayer array.

This is, however, merely illustrative. If desired, there may be greater or fewer near infrared pixels distributed throughout array 24. For example, array 24 may include one near infrared pixel in each 4×4 block of pixels, each 8×8 block of pixels, each 16×16 block of pixels, etc. As additional examples, there may be only one near infrared pixel for every other 2×2 block of pixels, there may be only one near infrared pixel for every five 2×2 blocks of pixels, there may be only one near infrared pixel in the entire array of pixels, or there may be a one or more rows, columns, or clusters of near infrared pixels in the array. In general, near infrared pixels may be scattered throughout the array in any suitable pattern. The example of FIG. 3 is merely illustrative.

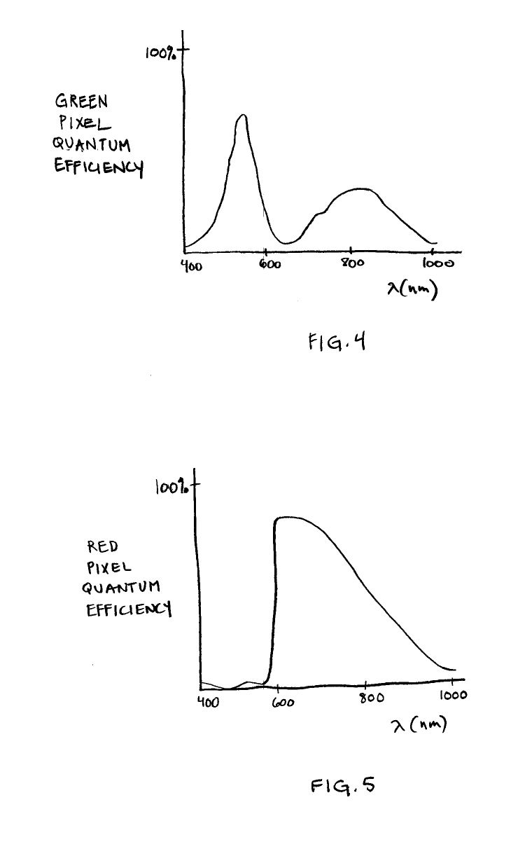

In addition to passing light of a given color, color filters 38C may be configured to pass light in the infrared spectral range as well. The transmittance properties of each color filter combined with the quantum efficiency of each photodiode allows the color pixels of array 24 to have the same sensitivity in the near infrared spectral range as the near infrared pixels. FIGS. 4, 5, 6, and 7 illustrate the quantum efficiencies of green, red, blue, and near infrared pixels, respectively, in array 24.

As shown in FIG. 4, green pixels exhibit high photon to electron conversion efficiency for wavelengths corresponding to green light. Green pixels may also exhibit sensitivity in the infrared spectral range. The quantum efficiency of green pixels at 850 nm may, for example, fall within the range of 17-18%.

As shown in FIG. 5, red pixels exhibit high photon to electron conversion efficiency for wavelengths corresponding to red light. Red pixels may also exhibit sensitivity in the infrared spectral range. The quantum efficiency of red pixels at 850 nm may, for example, fall within the range of 17-18%.

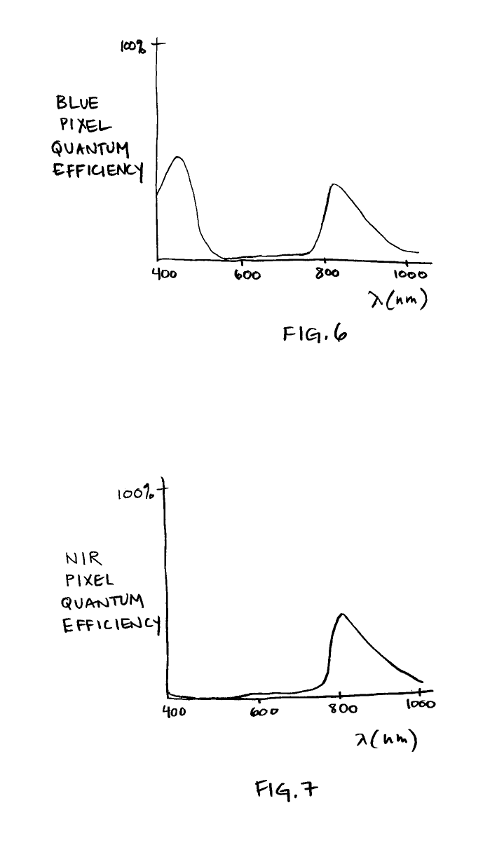

As shown in FIG. 6, blue pixels exhibit high photon to electron conversion efficiency for wavelengths corresponding to blue light. Blue pixels may also exhibit sensitivity in the infrared spectral range. The quantum efficiency of blue pixels at 850 nm may, for example, fall within the range of 17-18%.

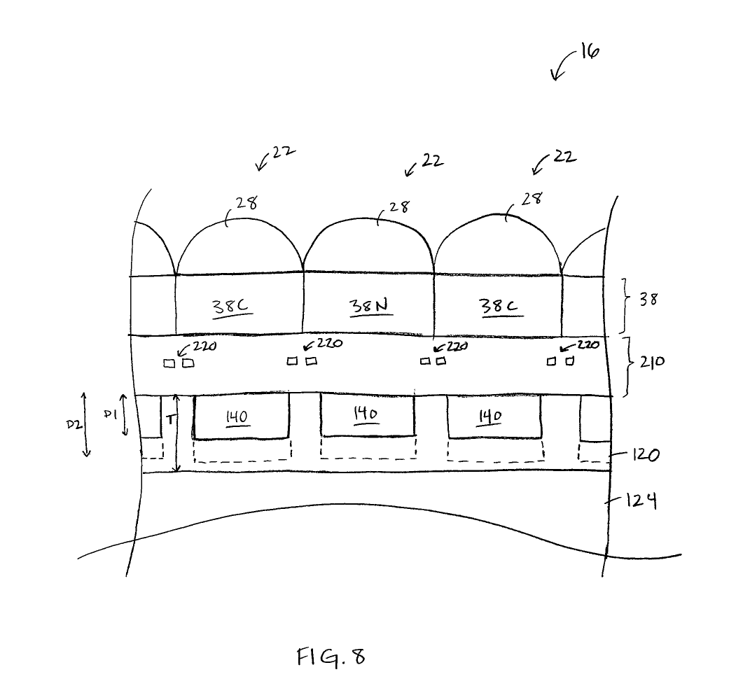

As shown in FIG. 7, near infrared pixels exhibit high photon to electron conversion efficiency for wavelengths corresponding to near infrared light. The quantum efficiency of infrared pixels at 850 nm may, for example, be about 17% or higher.

Thus, color pixels have an equal or nearly equal sensitivity in the near infrared spectral range as near infrared pixels. Near infrared pixels, on the other hand, are configured to receive only infrared light. With this type of arrangement, image sensor 16 can simultaneously capture images in the infrared spectral range as well as the visible spectral range. During color image capturing operations, color pixels may receive both visible light and infrared light. To improve the quality of the color images, the unwanted infrared portion of the pixel signal from the color pixels may be removed. The pixel signal from the near infrared pixels may be used to precisely determine how much to subtract from the pixel signals from the color pixels.

Alternatively, red, green, and blue pixels can be configured to respectively pass light in the red, green, and blue bands of the visual spectral range while blocking all or substantially all radiation in the infrared band of the spectral range that passes through the dual bandpass filter. With this type of configuration, the use of near infrared pixels to improve the quality of the color images may not be required.

During infrared image capturing operations, both infrared pixels as well as color pixels can be used to detect near infrared radiation. This is, however, merely illustrative. If desired, only the designated infrared pixels may be used to detect light in the near infrared spectral range. Infrared data gathered by infrared pixels and/or by color pixels may in turn be used for 3D imaging (e.g., depth imaging), automatic focusing, phase detection, and other applications.

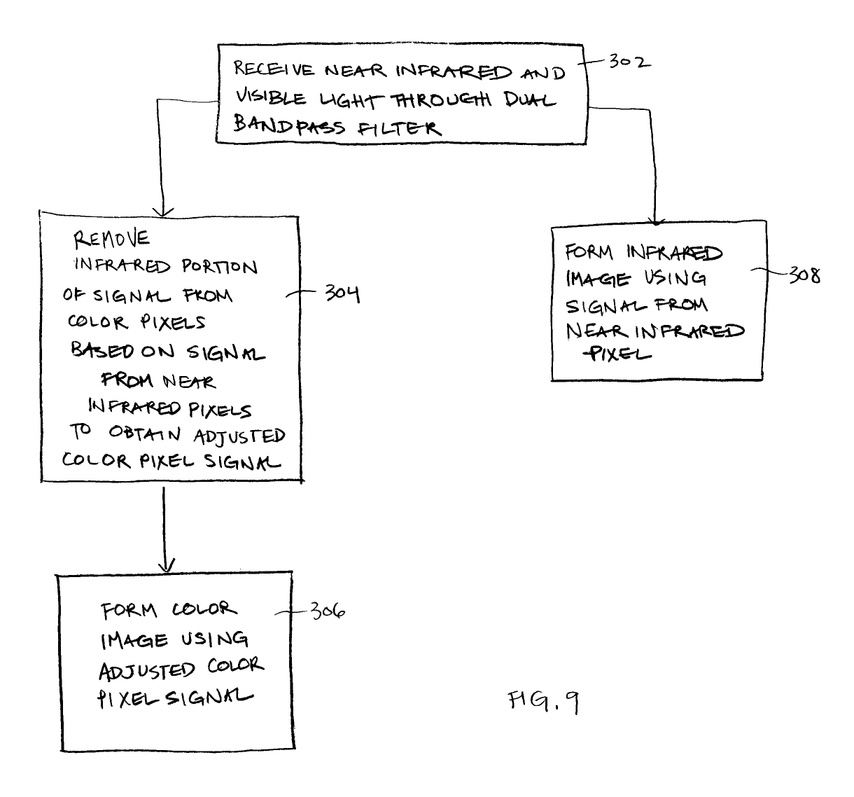

FIG. 8 is a cross-sectional side view of a portion of image sensor 16 that includes an array of front side illumination image sensor pixels. Each pixel 22 has a photosensitive element such as photodiode 140 formed in a substrate layer such as substrate layer 120 (e.g., an active p-type epitaxial layer grown on a silicon substrate such as substrate 124). As shown in FIG. 8, intermetal dielectric stack 210 may be formed on front surface of substrate 120. Dielectric stack 210 may include metal interconnect structures 220 formed in dielectric material (e.g., silicon dioxide, glass, or other suitable dielectric).

An array of color filter elements 38 may be formed over dielectric stack 210. A microlens 28 may be formed over each color filter element. Light can enter from the front side of the image sensor pixels 22 through microlenses 28. Each microlens 28 may direct light towards associated photodiode 140.

In order to optimize the near infrared response of sensor 16, the depth of photodiodes 140 may be increased from depth D1 to depth D2. In one suitable arrangement, both infrared pixels having infrared filters 38N as well as color pixels having color filters 38C may have photodiodes of depth D2. In another suitable arrangement, infrared pixels may have photodiodes of depth D2 whereas color pixels may have photodiodes of depth D1. The thickness T of epitaxial layer 120 may also be increased. Epitaxial layer 120 may, for example, have a thickness T of 4 microns, 5 microns, 6 microns, more than 6 microns, or less than 6 microns. Increasing the depth of photodiode 140 and/or the thickness of epitaxial layer 120 may increase the sensitivity of pixels 22 to infrared light.

The configuration of FIG. 8 in which image sensor 16 is a front side illumination image sensor is merely illustrative. If desired, image sensor 16 may be a back side illumination image sensor.

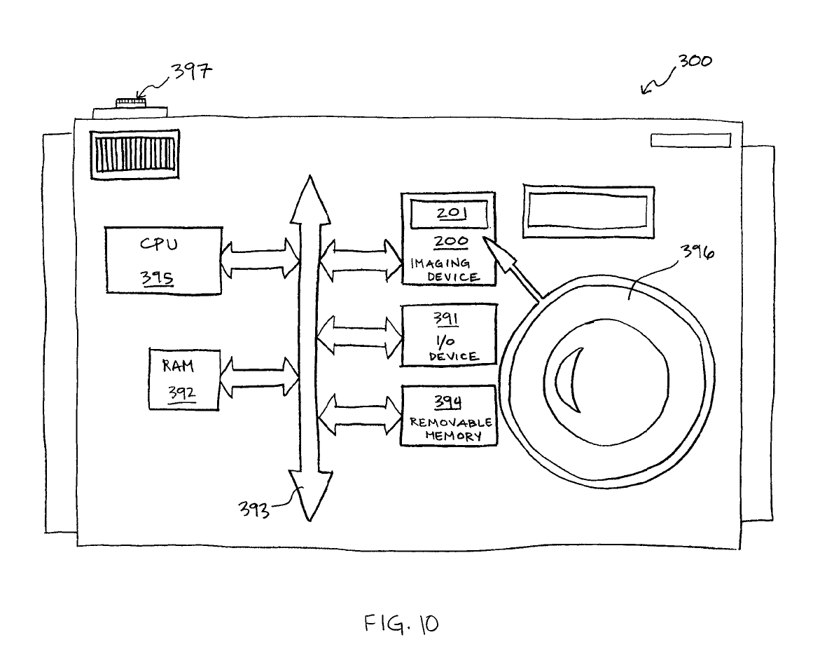

FIG. 9 is a flow chart of illustrative steps involved in simultaneously capturing visible and infrared images using an electronic device of the type shown in FIG. 1.

At step 302, image sensor 16 may receive both visible as well as infrared light through dual bandpass filter 20. The infrared light may, for example, be infrared light that has been generated by emitter 26 in device 10 and that has been reflected from a scene. The wavelength of infrared light that is generated by emitter 26 may correspond to the second narrow bandpass of dual bandpass filter 20.

At step 304, processing circuitry 18 may be used to determine an infrared portion of the color pixel signal using the near infrared pixel signal. Processing circuitry 18 may subtract the infrared portion from the color pixel signal to obtain an adjusted color pixel signal. The adjusted color pixel signal may be used to form a color image (step 306).

Infrared image capturing operations may be performed in parallel with color image capturing operations. As shown in FIG. 9, an infrared image may be formed using signals from the near infrared pixels in the pixel array.

FIG. 10 shows in simplified form a typical processor system 300, such as a digital camera, which includes an imaging device 200. Imaging device 200 may include a pixel array 201 of the type shown in FIG. 1 (e.g., pixel array 201 may be pixel array 24 of FIG. 1) formed on an image sensor SOC. Pixel array 201 may include color pixels and near infrared pixels as described above. A dual bandpass filter such as dual bandpass filter 20 of FIG. 1 may be arranged over pixel array 201. Processor system 300 is exemplary of a system having digital circuits that may include imaging device 200. Without being limiting, such a system may include a computer system, still or video camera system, scanner, machine vision, vehicle navigation, video phone, surveillance system, auto focus system, star tracker system, motion detection system, image stabilization system, and other systems employing an imaging device.

Processor system 300, which may be a digital still or video camera system, may include a lens such as lens 396 for focusing an image onto a pixel array such as pixel array 201 when shutter release button 397 is pressed. Processor system 300 may include a central processing unit such as central processing unit (CPU) 395. CPU 395 may be a microprocessor that controls camera functions and one or more image flow functions and communicates with one or more input/output (I/O) devices 391 over a bus such as bus 393. Imaging device 200 may also communicate with CPU 395 over bus 393. System 300 may include random access memory (RAM) 392 and removable memory 394. Removable memory 394 may include flash memory that communicates with CPU 395 over bus 393. Imaging device 200 may be combined with CPU 395, with or without memory storage, on a single integrated circuit or on a different chip. Although bus 393 is illustrated as a single bus, it may be one or more buses or bridges or other communication paths used to interconnect the system components.

Various embodiments have been described illustrating image sensor and/or system-on-chips that include both color pixels and near infrared pixels. An image sensor having color pixels and near infrared pixels may be used in conjunction with a dual bandpass filter that passes visible light as well as a narrow band of near infrared light. An image sensor SOC of this type may be capable of simultaneously capturing images in the visible and in the infrared spectral ranges and may be used in an imaging system such as an electronic device.

The dual bandpass filter may be interposed between a lens and the image sensor. The dual bandpass filter may be a bandpass coating filter that includes multiple layers of coating on a glass plate. Through a process of constructive and destructive interference, the dual bandpass filter may transmit visible light as well as a narrow band of near infrared light while blocking light of other wavelengths.

The image sensor may have a pixel array that includes both color pixels as well as near infrared pixels. Each color pixel may include a color filter formed over a photosensor, whereas each near infrared pixel may include a near infrared filter formed over a photosensor. The near infrared pixels may be scattered throughout the array in any suitable pattern. In one embodiment, the color filter array is formed in a quasi-Bayer pattern. With this type of arrangement, the array is composed of 2×2 blocks of filter 2 5 elements in which each block includes a green color filter element, a red color filter element, a blue color filter element, and a near infrared filter element in the place where a green color filter element would be located in a typical Bayer array. This is, however, merely illustrative. The density of near infrared pixels in the pixel array may be adjusted according to the requirements and/or the desired functionality of the image sensor.

The color pixels may be configured to detect both visible light as well as near infrared light. The near infrared pixels may be configured to detect only near infrared light. With this type of arrangement, the image sensor can simultaneously capture images in the visible spectral range as well as the infrared spectral range. During color image capturing operations, the infrared portion of the color pixel signal can be removed based on the signal received by the near infrared pixels. During infrared imaging operations, both near infrared and color pixels can be used in capturing infrared images or infrared images can be captured using the near infrared pixels exclusively.

In order to increase the sensitivity of the image sensor to infrared radiation, the thickness of the photodiode area and/or the thickness of the p-type epitaxial layer in which the photodiodes are formed may be increased. If desired, only the near infrared pixels may be provided with deepened photodiodes or both the near infrared and color pixels may be provided with deepened photodiodes.

The foregoing is merely illustrative of the principles of this invention which can be practiced in other embodiments.

What is claimed is:

1. A camera module, comprising:
an array of filter elements, wherein the array of filter elements includes color filter elements and infrared filter elements;
a dual bandpass filter arranged over the array of filter elements; and
an array of photosensitive elements, wherein each photosensitive element receives image light through the dual bandpass filter and an associated one of the filter elements.

2. The camera module defined in claim 1 wherein the dual bandpass filter comprises a plurality of coatings formed on a glass substrate and wherein the dual bandpass filter is configured to transmit visible light and infrared light.

3. The camera module defined in claim 1 further comprising a lens, wherein the dual bandpass filter is interposed between the array of filter elements and the lens.

4. The camera module defined in claim 1 wherein the array of filter elements comprises at least one two-by-two block of filter elements and wherein the at least one two-by-two block of filter elements comprises a green color filter element, a red color filter element, a blue color filter element, and a near infrared filter element.

5. The camera module defined in claim 1 wherein the array of filter elements comprises a plurality of two-by-two blocks of filter elements, wherein each of the two-by-two blocks of filter elements comprises a green color filter element, a red color filter element, a blue color filter element, and a near infrared filter element, and wherein the plurality of two-by-two blocks of filter elements makes up the entire array of filter elements.

6. The camera module defined in claim 1 wherein each of the color filter elements is configured to transmit a first range of wavelengths corresponding to light of a given color and a second range of wavelengths corresponding to near infrared light.

7. The camera module defined in claim 6 wherein each of the infrared filter elements is configured to transmit a range of wavelengths corresponding to near infrared light.

8. The camera module defined in claim 1 further comprising a plurality of microlenses, wherein the array of filter elements is interposed between the plurality of microlenses and the array of photosensitive elements.

9. The camera module defined in claim 1 wherein all of the photosensitive elements in the array of photosensitive elements are configured to receive infrared light.

10. The camera module defined in claim 1 wherein each of the color filter elements is configured to transmit a range of wavelengths corresponding to light of a given color while blocking infrared light.

11. A method for operating an electronic device having a camera module, wherein the camera module comprises a dual bandpass filter arranged over an image sensor having color pixels and infrared pixels, the method comprising:
with the color pixels, receiving visible light and infrared light through the dual bandpass filter and generating a color pixel signal based on the received visible and infrared light;
with the infrared pixels, receiving infrared light through the dual bandpass filter and generating an infrared pixel signal based on the received infrared light;
with processing circuitry in the electronic device, determining an infrared portion of the color pixel signal based on the infrared pixel signal; and
with the processing circuitry, removing the infrared portion from the color pixel signal.

12. The method defined in claim 11 wherein removing the infrared portion comprises subtracting a value proportional to the infrared pixel signal from the color pixel signal.

13. The method defined in claim 11 wherein removing the infrared portion from the color pixel signal comprises removing the infrared portion from the color pixel signal to obtain an adjusted color pixel signal, the method further comprising forming a color image using the adjusted color pixel signal.

14. The method defined in claim 11 further comprising forming an infrared image using the infrared pixel signal.

15. The method defined in claim 11 wherein the electronic device comprises an emitter, the method further comprising:
with the emitter, illuminating a scene with the infrared light.

16. A system, comprising:
a central processing unit;
memory;
input-output circuitry; and
an imaging device, wherein the imaging device comprises:
an array of photosensitive elements,
a bandpass filter configured to pass visible and infrared light, and
an array of filter elements interposed between the bandpass filter and the array of photosensitive elements, wherein the array of filter elements comprises a plurality of color filter elements and a plurality of infrared filter elements.

17. The system defined in claim 16 further comprising an infrared light source configured to illuminate a scene with infrared light.

18. The system defined in claim 16 wherein the plurality of color filter elements comprises red color filter elements, green color filter elements, and blue color filter elements and wherein each color filter element in the plurality of color filter elements is configured to transmit light of a given color and near infrared light.

19. The system defined in claim 16 wherein the bandpass filter comprises a plurality of optical coatings formed on a glass plate.

20. The system defined in claim 16 wherein the array of filter elements comprises at least one two-by-two block of filter elements having a red color filter element, a green color filter element, a blue color filter element, and an infrared filter element.

21. The system defined in claim 16 wherein the imaging device comprises a front side illumination imaging device.
